(19) United States
(12) Patent Application Publication
(10) Pub. No.: US 2014/0209961 A1
(43) Pub. Date: Jul. 31, 2014

(54) ALTERNATING CURRENT LIGHT EMITTING DIODE FLIP-CHIP

(71) Applicant: LUXO-LED CO., LIMITED, Hong Kong (HK)

(72) Inventor: Shih-Yang TSO, Taipei City (TW)

(73) Assignee: LUXO-LED CO., LIMITED, Hong Kong (HK)

(21) Appl. No.: 14/167,861

(22) Filed: Jan. 29, 2014

Related U.S. Application Data
(60) Provisional application No. 61/758,613, filed on Jan. 30, 2013.

(51) Int. Cl. H01L 33/62

(52) U.S. Cl. CPC H01L 33/62
USPC 257/99

(57) ABSTRACT

An alternating current light emitting diode flip chip is provided. The flip chip includes an alternating current light emitting diode chip having a first bond pad and a second bond pad formed thereon. A first solder ball is disposed on the first bond pad and a second solder ball is disposed on the second bond pad. A flip-chip bonding process is performed to bond a carrier substrate with the first solder ball and the second solder ball.

### CROSS REFERENCE TO RELATED APPLICATION

The application claims priority based on U.S. provisional application, Ser. No. 61/758,613, filed Jan. 30, 2013 entitled ALTERNATING CURRENT LIGHT EMITTING DIODE FLIP-CHIP, which is hereby incorporated by reference in its entirely.

### BACKGROUND

1. Technical Field

The disclosure relates to an alternating current light emitting diode flip-chip.

2. Related Art

Light emitting devices (LEDs) are semiconductor devices that produce light when a current is supplied to them. LEDs are capable of emitting light in various colors through a light source by varying materials of a compound semiconductor, such as GaAs, AIGaAs, GaN, InGaInP, and the like. In general, the LED is manufactured in a package form.

LEDs are intrinsically DC devices that only pass current in one polarity and historically have been driven by DC voltage sources using resistors, current regulators and voltage regulators to limit the voltage and current delivered to the LED. Some LEDs have resistors built into the LED package providing a higher voltage LED typically driven with 5V DC or 12V DC. With proper design considerations LEDs may be driven more efficiently with AC than with DC drive schemes.

Recently, the LED package being developed and manufactured is in a flip chip structure. The flip chip LED package may be manufactured by forming a solder bump on an electrode pad provided in an LED, performing a reflow process, and flip-chip bonding the LED to a package substrate. However no AC LED is manufactured using the flip chip process. Thus there is a need to develop an AC LED package in a flip chip structure.

### SUMMARY

The embodiment of the disclosure discloses an alternating current light emitting diode flip chip is provided. The flip chip includes an alternating current light emitting diode chip having a first bond pad and a second bond pad formed thereon. A first solder ball is disposed on the first bond pad and a second solder ball is disposed on the second bond pad. A flip-chip bonding process is performed to bond a carrier substrate with the first solder ball and the second solder ball.

The detailed characteristics and advantages of the disclosure are described in the following embodiments in details, the techniques of the disclosure can be easily understood and embodied by a person of average skill in the art, and the related objects and advantages of the disclosure can be easily understood by a person of average skill in the art by referring to the contents, the claims and the accompanying drawings disclosed in the specifications.

### BRIEF DESCRIPTION OF THE DRAWINGS

The present disclosure will become more fully understood from the detailed description given herein below for illustration only, and thus are not limitative of the present disclosure, and wherein:

FIG. 1 illustrates an alternating current light emitting diode flip chip according to one embodiment of the disclosure.

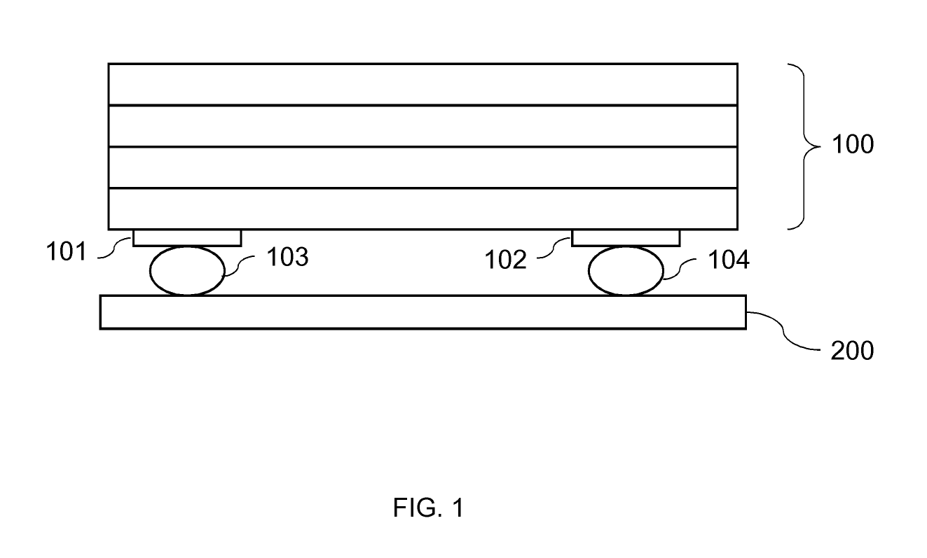

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The figure illustrates an alternating current light emitting diode flip chip according to one embodiment of the disclosure.

The flip chip includes an alternating current light emitting diode chip 100 having a first bond pad 101 and a second bond pad 102 formed thereon. A first solder ball 103 is disposed on the first bond pad 101 and a second solder ball 104 is disposed on the second bond pad 102. A flip-chip bonding process is performed to bond a carrier substrate 200 with the first solder ball 103 and the second solder ball 104.

The first bond pad 101 and the second bond pad 102 are used to apply a voltage to the alternating current light emitting diode chip 100, so that the alternating current light emitting diode chip 100 is activated to emit light.

The first solder ball 103 and the second solder ball 104 may be formed of commonly used solder materials, such as lead-free solders, eutectic solders, or the like.

The alternating current light emitting diode chip contains a substrate formed therein.

The material of the substrate is one selected from a sapphire material, a silicon carbide material, and a silicon germanium material.

The carrier substrate 200 may be a semiconductor substrate, such as a silicon substrate, or may be a dielectric substrate.

According, the method of forming an alternating current light emitting diode flip chip comprises the following steps. First, an LED chip comprising a first bond pad and a second bond pad is provided. Then the first bond pad and the second bond pad are bonded onto a carrier substrate through flip-chip bonding through soldering a first solder ball and a second solder ball.

Although the embodiments and their advantages have been described in detail, it should be understood that various changes, substitutions, and alterations can be made herein without departing from the spirit and scope of the embodiments as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. An alternating current light emitting diode flip-chip, comprising:
an alternating current light emitting diode chip;
a first bond pad disposed on the alternating current light emitting diode chip;
a second bond pad disposed on the alternating current light emitting diode chip;
a carrier substrate;
a first solder ball, disposed between the first bond pad and the carrier substrate; and
a second solder ball, disposed between the second bond pad and the carrier substrate.

2. The alternating current light emitting diode flip-chip according to claim 1, wherein a flip-chip bonding process is performed to bonding the carrier substrate and the alternating current light emitting diode chip.

3. The alternating current light emitting diode flip-chip according to claim 1, wherein the carrier substrate is a semiconductor substrate

4. The alternating current light emitting diode flip-chip according to claim 1, wherein the carrier substrate is a dielectric substrate.
